(19) United States
(12) Patent Application Publication
(10) Pub. No.: US 2007/0150798 A1
(43) Pub. Date: Jun. 28, 2007

(54) METHOD FOR DECODING AN ECC BLOCK AND RELATED APPARATUS

(76) Inventors: Jia-Horng Shieh, Taipei County (TW); Pi-Hai Liu, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/164,959

(22) Filed: Dec. 12, 2005

(51) Int. Cl. H03M 13/00

(52) U.S. Cl. 714/785

(57) ABSTRACT

A method for decoding an error correction code (ECC) block includes: providing a plurality of flags, wherein each flag is utilized to label at least one codeword of the ECC block as an error-free codeword; and detecting whether a flag corresponding to a specific codeword is asserted, and skipping calculating a syndrome of the specific codeword if the flag is asserted.

### BACKGROUND

The invention relates to a decoding method and related decoding apparatus, and more particularly, to a method for decoding an ECC block and related apparatus.

A DVD has become a popular storage medium because of its large storage space. In the related art, when data stored in a DVD is to be utilized, the data is firstly read from the DVD. Because the DVD disc data may have multiple errors and the DVD disc data is generated by processing original data through an 8-14 modulation, we have to utilize an EFM+ demodulator to demodulate the DVD disc data to form a row data. Please note that because the DVD disc data have multiple errors, the row data apparently have corresponding errors in it. And then, each row data is stored in a memory buffer. An error correction code (ECC) block is formed when the stored row data in the memory buffer is sufficient to form a complete block. The ECC block is then decoded through a Reed Soloman Product Code (RSPC) decoding procedure to obtain the original data by correcting the errors in the row data.

Please refer to FIG. 1, which is a diagram of an ECC block 100 according to the related art. As shown in FIG. 1, the ECC block 100 comprises 208 rows and 192 columns, wherein each row can be called as a PI codeword, and each column can be called as a PO codeword. Moreover, the previous 192 rows are generated by encoding the DVD's disc data, and the last 16 rows are outer-code parity (PO) data, utilized for correcting errors of each PO codeword. Similarly, the previous 182 columns are generated by encoding the DVD's disc data, and the last 10 columns are inner-code parity (PI) data, utilized for correcting errors of each PI codeword. As mentioned previously, the ECC block 100 is then decoded to correct any errors that may exist in the ECC block 100. The operation of correcting errors will be illustrated in detail in the following disclosure.

Please refer to FIG. 2, which is a diagram of a decoding device 200. The decoding device 200 comprises a memory buffer 210 for storing the above-mentioned ECC block 100, a syndrome calculator 220 coupled to the memory buffer for calculating a syndrome of each codeword, an error corrector 230 coupled to the syndrome calculator 220 and the memory buffer 210 for correcting errors of each codeword in the memory buffer 210 according to the calculated syndrome, and a controller 240 coupled to the syndrome calculator 220 and the error corrector 230 for controlling the operation of the entire decoding device 200. Please note that the detailed operation and functions of the decoding device will be illustrated later.

Please refer to FIG. 3, which is a flow chart of correcting errors of the ECC block 100 shown in FIG. 1 by utilizing the decoding device 200 shown in FIG. 2. The flow comprises following steps.

Step 300: Start;

Step 302: Decode all PI codewords;

Step 304: Decode all PO codewords;

Step 306: If all PI and PO codewords are decodable, go to step 312; otherwise, go to step 308

Step 308: Calculate the number of repetitions that occurred for decoding the PI/PO codewords. If the number of decoding repetitions for the PI/PO codewords is larger than a predetermined number, go to step 310; otherwise, go to step 302.

Step 310: Failed.

Step 312: Finished.

First, the decoding device 200 begins decoding the ECC block 100 (step 302). Second, the decoding device 200 begins executing a PI decoding operation on each PI codeword for correcting errors of the PI codeword. Now taking one PI decoding operation as an example, first, the PI decoding operation is performed on row 1 (the first PI codeword ). That is, the syndrome calculator 220 calculates a syndrome of row 1 by reading row 1 from the memory buffer 210. As known by those skilled in the art, the syndrome calculator 220 utilizes a polynomial for calculating the syndrome of row 1. If the calculated syndrome is 0, this means that row 1 is decodable (i.e., row 1 is error-free.) On the other hand, if the calculated syndrome is not 0, this means that row 1 needs to be corrected. Therefore, the error corrector 230 receives the calculated syndrome, and utilizes the syndrome to calculate error locations and error values corresponding to the error locations. And then, the error corrector 230 reads the error data from the memory buffer 210 according to the error location, and corrects the error by performing an XOR logic operation on the error value and the error data. Therefore, some errors of the row 1 are corrected through the above-mentioned error correction operation. And then, the same process is performed on row 2. That is, the operations includes calculating the syndrome of row 2, determining error values and corresponding error locations of row 2, and correcting errors according to the error locations and error values. Moreover, the same process is orderly performed on row 3, row 4, . . . , until row 208. Therefore, some errors of the ECC block are corrected after the PI decoding operation is performed on all PI codewords.

Please note, because of the error-correcting ability of the PI decoding (for example, correcting three errors at one PI decoding on each PI codeword), even after the PI decoding operation is performed on all PI codewords, there are still some errors in the ECC block. Therefore, after the PI decoding operation, the PO decoding operation has to be performed.

Similarly, the errors of the PO codewords are corrected through the above-mentioned error correction operation (Step 304). That is, the syndrome of a PO codeword is calculated. And the error locations and corresponding error values are determined by the syndrome. At last, some errors of a PO codeword are corrected. Furthermore, the PO decoding operation is also sequentially performed from column 1 to column 172. Therefore, after step 302 and step 304 are performed, it can be known that a plurality of errors of the ECC block 100 have been corrected. However, it is still possible that some errors may have not been corrected at this point. Therefore, step 302 and step 304 must be repeatedly performed to try to correct all of the errors.

There can exist an instance that there are a great number of errors in the ECC block 100. There may be an abundance of errors such that the PI/PO data are insufficient for regenerating the DVD's original data. Therefore, the controller 240 must count the number of repetitions that occurred for step 302 or step 304 (step 306). If the number of repetitions is larger than a predetermined number, the controller 240 determines that the ECC block 100 is not decodable. In the case of too many repetitions, for example, the number of repetitions is larger than the predetermined number, the entire decoding operation fails (step 308). On the other hand, if the number of repetitions is smaller than the predetermined number, the decoding operation is performed with execution flow going back to step 302 again to perform another error correction. At last, all errors of the entire ECC block 100 can be corrected and the ECC block 100 can be decoded and the DVD's original data can be regenerated.

The decoding operation just described includes inherent performance deficiencies. That is, whenever a single PI/PO decoding operation is performed, the syndromes of all of the PI/PO codewords are calculated, every time, regardless of our knowing that the syndrome of a specific codeword is 0. Utilizing scarce system resources to repeatedly calculate the syndrome having the value of 0 result in inefficiency and cause the decoding operation to perform slower.

### SUMMARY

It is therefore one of primary objectives of the claimed invention to provide a method for decoding an ECC block, to solve the above-mentioned problem.

According to an exemplary embodiment of the claimed invention, a method for decoding an ECC block is disclosed. The method comprises: providing a plurality of flags, wherein each flag is utilized to label at least one codeword of the ECC block as an error-free codeword; and detecting whether a flag corresponding to a specific codeword is asserted, and skipping the operation of calculating a syndrome of the specific codeword if the flag is asserted.

According to another exemplary embodiment of the claimed invention, a decoding device for decoding an ECC block is disclosed. The decoding device comprises: a storage device for storing the ECC block and a plurality of flags, wherein each flag is utilized to label at least one codeword of the ECC block as an error-free codeword; a syndrome calculator; and a controller for detecting whether a flag corresponding to a specific codeword is asserted, and controlling the syndrome calculator to skip the operation of calculating a syndrome of the specific codeword if the flag is asserted.

The claimed invention can prevent the operation of repetitively calculating the syndrome having the value 0. Therefore, the claimed invention only decoded the codewords that really require correcting. This can save significant processing time and system resources. In other words, the claimed invention performs the decoding operation more efficiently and requires less system resources than the related art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an ECC block according to the related art.

FIG. 2 is a diagram of a decoding device according to the related art.

FIG. 3 is a flow chart of correcting errors of the ECC block shown in FIG. 1 by utilizing the decoding device shown in FIG. 2.

FIG. 4 is a diagram of a decoding device according to the present invention.

FIG. 5 is a diagram of an ECC block according to the present invention.

FIG. 6-1 and FIG. 6-2 are a flow chart of a PI decoding operation according to the present invention.

FIG. 7-1 and FIG. 7-2 are a flow chart of a PO decoding operation according to the present invention.

FIG. 8 is a flow chart of correcting errors in the ECC block shown in FIG. 5 of another embodiment according to the present invention.

FIG. 9-1 and FIG. 9-2 illustrates the PI decoding operation according to the flow chart shown in FIG. 8.

FIG. 10-1 and FIG. 10-2 illustrates the PO decoding operation according to the flow chart shown in FIG. 8.

### DETAILED DESCRIPTION

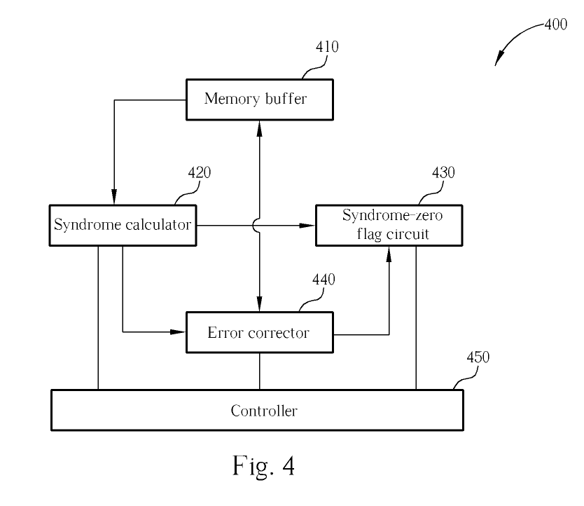

Please refer to FIG. 4, which is a diagram of a decoding device 400 according to the present invention. As shown in FIG. 4, the decoding device 400 comprises a memory buffer 410, a syndrome calculator 420, a syndrome-zero flag circuit 430, an error corrector 440, and a controller 450. The controller 450 is coupled to the syndrome calculator 420, the syndrome-zero flag circuit 430, and the error corrector 440. The memory buffer 410 is coupled to the syndrome calculator 420, and the error corrector 440. Furthermore, the error corrector 440 is coupled to the syndrome calculator 420 and the syndrome-zero flag circuit 430. And the syndrome calculator 420 is coupled to the syndrome-zero flag circuit 430. In this embodiment, the operations and functions of the memory buffer 410, the syndrome calculator 420, and the error corrector 440 are substantially the same as the components of the related art decoding device 200. And the detailed operations and functions of the other components of the decoding device 400 will be illustrated in the following disclosure.

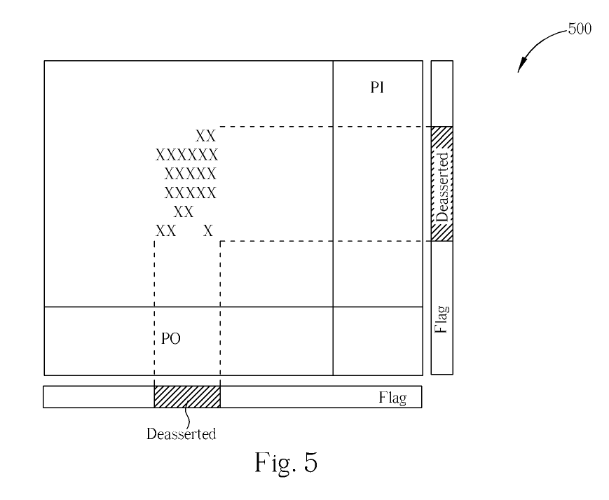

Please refer to FIG. 5, which is a diagram of an ECC block 500 according to the present invention. As shown in FIG. 5, the ECC block 500 is similar to the above-mentioned ECC block 100. The difference is that the ECC block 500 further comprises a plurality of flags. Please note that in this embodiment, a flag can be a 1-bit register utilized for labeling the condition of a specific codeword. The flag can be store in memory or registers.

For example, in the operation of decoding the ECC block 500, as mentioned previously, a syndrome of the specific codeword is firstly calculated, and if the calculated syndrome is 0, this means that the specific codeword may be an error-free codeword. Therefore, in the present invention, if the calculated syndrome corresponds to 0, the flag is asserted by the syndrome-zero flag circuit 430 such that the controller 450 can control the whole decoding device 400 according to the flag to determine whether to skip decoding the specific codeword. In other words, if the flag is detected as being asserted, the codeword corresponding to the asserted flag is regarded as an error-free codeword. The present invention decoding device 400 efficiently eliminates repetitive operations for the error-free codeword. Therefore, in the present invention, the decoding device 400 only interacts with the codewords not corresponding to the asserted flag, which means the codewords should have errors. This makes the present invention more efficient.

As shown in FIG. 5, the ECC block 500 has a plurality of errors that are labeled as X. The codewords containing errors have corresponding flags deasserted, which means the codewords might have errors. Therefore, the controller 450 is able to control the decoding device 400 according to the flags.

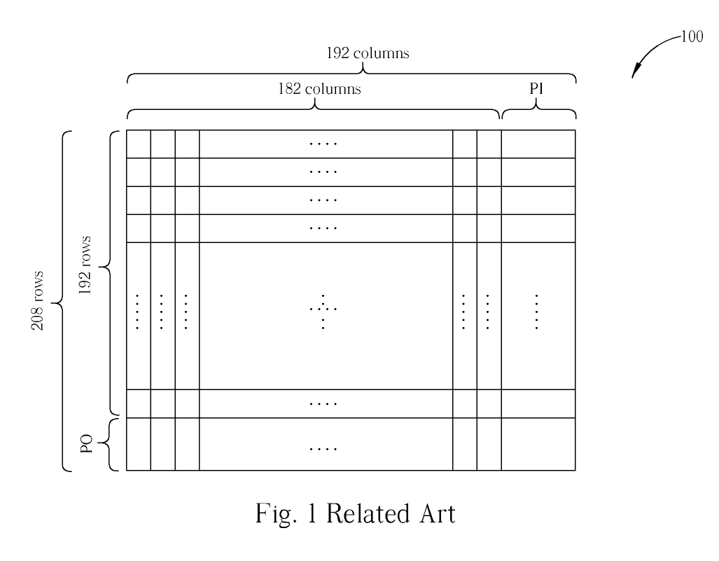

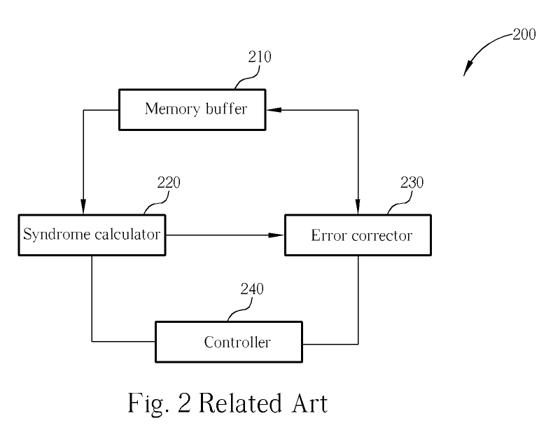

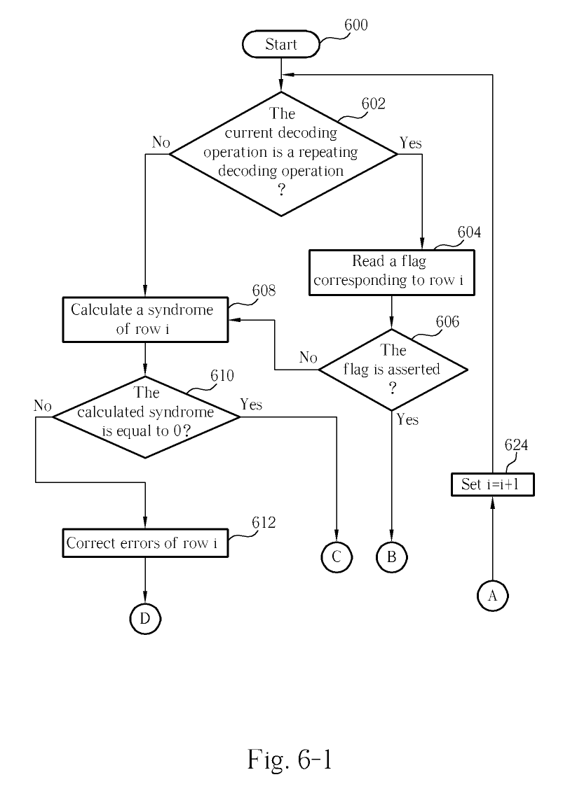

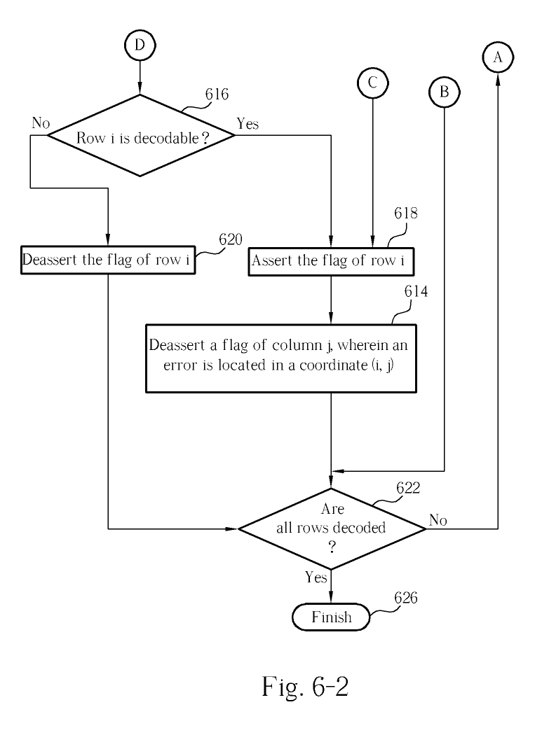

Please refer to FIGS. 6-1 and FIG. 6-2, which are flow charts of a PI decoding operation according to the present invention. The flow comprises the following steps.

Step 600: Start;

Step 602: Detect whether the current decoding operation is a repeating decoding operation? If the current decoding operation is a repeat decoding operation, then go to step 604; otherwise, go to step 608;

Step 604: Read a flag corresponding to row i;

Step 606: Detect whether the flag is asserted; if the flag is asserted, then go to step 622; otherwise, go to step 608;

Step 608: Calculate a syndrome of row i;

Step 610: Detect whether the calculated syndrome is equal to 0; if the calculated syndrome is equal to 0, then go to step 618, otherwise; go to step 612;

Step 612: Correct errors of row i;

Step 616: Detect whether row i is decodable; if row i is decodable, then go to step 618; otherwise, go to step 620;

Step 618: Assert the flag of row i;

Step 614: Deassert a flag of column j, wherein an error is located in a coordinate (i, j);

Step 620: Deassert the flag of row i;

Step 622: Are all rows decoded? If all rows are decoded, then go to step 626; otherwise, go to step 624;

Step 624: Set i=i+1, and go back to step 602;

Step 626: Finish.

First, the PI decoding operation is ready to start (Step 600). The controller 450 detects whether the current PI decoding operation is a repeating decoding operation (Step 602). Because all flags are set as being asserted (set the flag as 1) or deasserted (set the flag as 0) after the first PI decoding operation is completed, the flag is utilized to represent the condition of each codeword after the first PI decoding operation.

Therefore, if the current PI decoding operation is the first PI decoding operation, the controller 450 directly utilizes the syndrome calculator 420 to calculate a syndrome of a current PI codeword (step 608), for example, current row i, wherein i is an integer.

Alternatively, if the current PI decoding operation is not the first PI decoding operation, then each flag should have been set in the first PI decoding operation.

Therefore, the controller 450 reads a flag corresponding to the specific PI codeword to detect if the flag is asserted (Step 604). If the flag is asserted, the controller 450 knows that the current PI codeword does not require processing. Therefore, the decoding device 400 goes directly to step 622 to continue with the processing of a next PI codeword. (that is, in step 624, get the next PI codeword by setting i=i+1) or finish the entire flow if all of the PI codewords are completely processed (Step 626). On the other hand, if the flag is not asserted, the controller 450 knows that the current PI codeword must be processed. Therefore, the controller 450 utilizes the syndrome calculator 420 to calculate the syndrome of the current PI codeword (step 608).

After step 608, the controller 450 detects whether the calculated syndrome is equal to 0. If the calculated syndrome is equal to 0, this means that the current PI codeword is an error-free codeword (Step 610). Therefore, the controller 450 controls the syndrome-zero flag circuit 430 to assert the flag (Step 618). Then, the decoding device 400 goes to step 622 to continue the processing of a next PI codeword (that is, in step 624, get the next PI codeword by setting i=i+1) or finish the entire flow if all of the PI codewords are completely processed (Step 626).

Furthermore, if the calculated syndrome is not equal to 0, this means that the current PI codeword contains at least one error. Therefore, the controller 450 controls the error corrector 440 to correct the error of the PI codeword (Step 612). And then, the controller 450 detects whether the current PI codeword is decodable, in other words, the controller 450 detects whether the PI codeword is an error-free codeword (Step 616).

At this time, if the current PI codeword is not decodable, this means that the current PI codeword still contains errors. Therefore, the controller 450 controls the syndrome-zero flag circuit 430 to deassert the flag corresponding to the current PI codeword (Step 620). On the other hand, if the current PI codeword is decodable, the controller controls the syndrome-zero flag circuit 430 to assert the flag corresponding to the current PI codeword (Step 618). Because the value of the corrected error has been changed, this directly influences the syndrome of the PO codeword having the error. For example, if the coordinate of an error is (i, j), and if the value of the error is corrected, then the syndrome of column j will be changed. Therefore, in this embodiment, the controller 450 controls the syndrome-zero flag circuit 430 to deassert a flag of a PO codeword according to the error location. That is, the syndrome-zero flag circuit 430 deasserts the flag of column j (Step 614). Then the decoding device 400 goes to the step 622 to continue the processing of a next PI codeword (that is, in step 624, get the next PI codeword by setting i=i+1) or finish the entire flow if all of the PI codewords are completely processed (Step 626).

Please note that in step 602, the controller 450 can count the number of repeating decoding operations for the PI codeword. Similar to the related art, the controller 450 can stop the entire decoding operation if the number of repetitions is larger than a predetermined value. This change also obeys the spirit of the present invention.

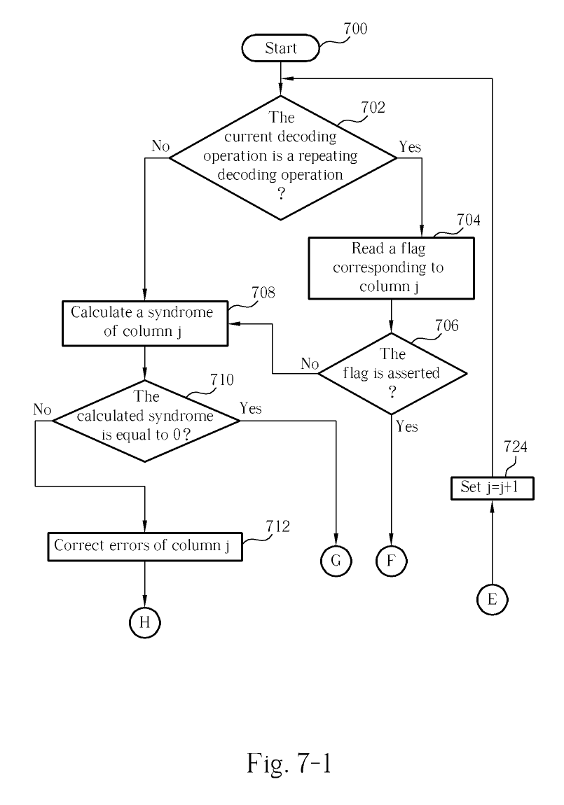

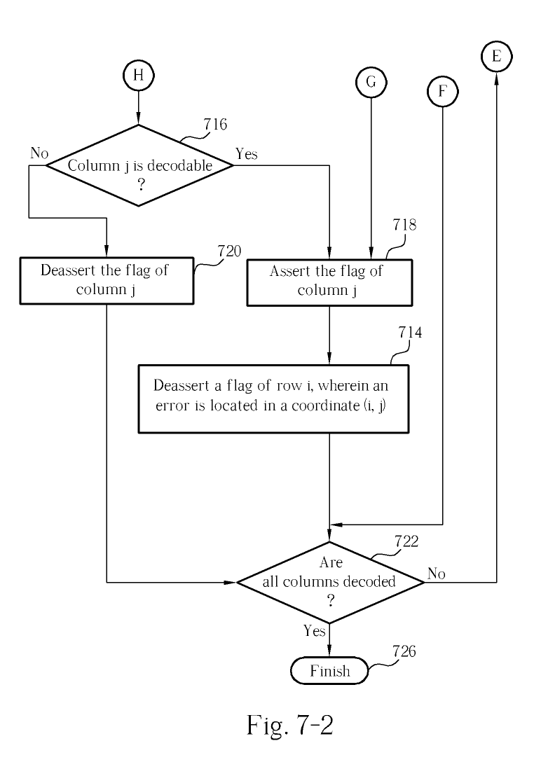

Please refer to FIGS. 7-1 and 7-2, which are a flow chart of a PO decoding operation according to the present invention. The flow comprises following steps:

Step 700: Start;

Step 702: Detect whether the current decoding operation is a repeating decoding operation? If the current decoding operation is a repeat decoding operation, then go to step 704; otherwise, go to step 708;

Step 704: Read a flag corresponding to column j;

Step 706: Detect whether the flag is asserted; if the flag is asserted, then go to step 822; otherwise, go to step 808;

Step 708: Calculate a syndrome of column j;

Step 710: Detect if the calculated syndrome is equal to 0; if the calculated syndrome is equal to 0, then go to step 718, otherwise; go to step 712;

Step 712: Correct errors of column j;

Step 716: Detect whether column j is decodable; if column j is decodable, then go to step 718; otherwise, go to step 720;

Step 718: Assert the flag of column j; and then go to step 714;

Step 714: Deassert a flag of row i, wherein an error is located in a coordinate (i, j); and then go to step 722;

Step 720: Deassert the flag of column j;

Step 722: Are all columns decoded? If all columns are decoded, then go to step 726; otherwise, go to step 724;

Step 724: Set j=j+1, and go back to step 702;

Step 726: Finish.

Please note that the flow of the PO decoding operation is symmetric to the PI decoding operation.

First, after the above-mentioned PI decoding operation is performed on all PI codewords, the PO decoding operation is ready to start (Step 700). The controller 450 detects whether the current PO decoding operation is a repeating decoding operation (Step 702). Because all flags are set as being asserted or deasserted after the above-mentioned PI decoding operation or previous PO decoding operation. Similarly, the flag of each PO codeword is also utilized to represent the condition of each codeword.

Therefore, assuming that the current PO decoding operation is the first PO decoding operation, this means all flags are deasserted. Therefore, the controller 450 directly utilizes the syndrome calculator 420 to calculate a syndrome of a current PO codeword (step 708), for example, to calculate a syndrome of current column j, wherein j is an integer.

Alternatively, if the current PO decoding operation is not the first PO decoding operation, this means that each flag should have been set (asserted or deasserted) in the previous PO/PI decoding operations.

Therefore, the controller 450 reads a flag corresponding to the current PO codeword (column j) to detect if the flag is asserted (Step 704). If the flag is asserted, the controller 450 knows that the current PO codeword does not require processing. Therefore, the decoding device 400 goes directly to step 722 to continue with the processing of a next PO codeword. (that is, in step 724, get the next PO codeword by setting j=j+1) or finish the entire flow if all of the PO codewords are completely processed (Step 726). On the other hand, if the flag is not asserted, the controller 450 knows that the current PO codeword must be processed. Therefore, the controller 450 utilizes the syndrome calculator 420 to calculate the syndrome of the current PO codeword (step 708).

After step 708, the controller 450 detects whether the calculated syndrome is equal to 0. If the calculated syndrome is equal to 0, this means that the current PO codeword is an error-free codeword (Step 710). Therefore, the controller 450 controls the syndrome-zero flag circuit 430 to assert the flag (Step 718). This means that in a next PO decoding operation, there is no need to process the current column j again.

Then, the decoding device 400 goes to step 722 to continue the processing of a next PO codeword (that is, in step 724, get the next PO codeword by setting j=j+1) or finish the entire flow if all of the PO codewords are completely processed (Step 726).

Furthermore, if the calculated syndrome is not equal to 0, this means that the current PO codeword contains at least one error. Therefore, the controller 450 controls the error corrector 440 to correct the error of the PO codeword (Step 712). And then, the controller 450 detects whether the current PO codeword is decodable, in other words, the controller 450 detects whether the PO codeword is an error-free codeword (Step 716).

At this time, if the current PO codeword is not decodable, this means that the current PO codeword still contains errors. Therefore, the controller 450 controls the syndrome-zero flag circuit 430 to deassert the flag corresponding to the current PO codeword (Step 720). On the other hand, if the current PO codeword is decodable, the controller controls the syndrome-zero flag circuit 430 to assert the flag corresponding to the current PO codeword (Step 718). Because the value of the corrected error has been changed, this directly influences the syndrome of the PI codeword having the error. For example, if the coordinate of an error is (i, j), and if the value of the error is corrected, then the syndrome of row i will be changed. Therefore, in this embodiment, the controller 450 controls the syndrome-zero flag circuit 430 to deassert a flag of a PI codeword according to the error location. That is, the syndrome-zero flag circuit 430 deasserts the flag of row i (Step 714). Then the decoding device 400 goes to the step 722 to continue the processing of a next PO codeword (that is, in step 724, get the next PO codeword by setting j=j+1) or finish the entire flow if all of the PO codewords are completely processed (Step 726).

Please note that in step 702, the controller 450 can count the number of repeating decoding operations for the PO codeword. Similar to the related art, the controller 450 can stop the entire decoding operation if the number of repetitions is larger than a predetermined value. This change also obeys the spirit of the present invention.

After the PO decoding operation is finished, as mentioned previously, some errors may be still in the ECC block. Therefore, the whole flow goes into the step 600 again to perform the PI decoding operation. It is similar to the related art flow (step 302˜step 308). That is, the PI decoding operation and the PO decoding operation may have to be performed for several times to correct all the errors of the ECC block. Or, if the repetitions are too many, the whole error-correction operation fails.

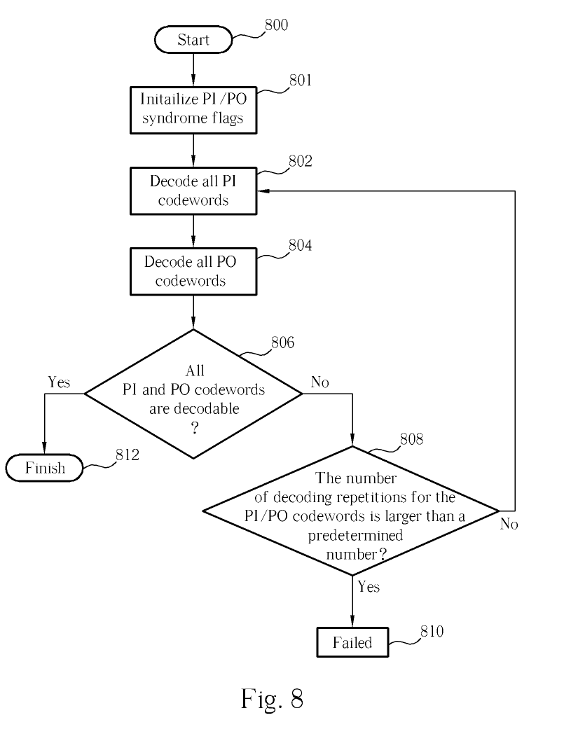

Please refer to FIG. 8, which is a flow chart of correcting errors in the ECC block shown in FIG. 5 of another embodiment according to the present invention. It comprises the following steps:

Step 800: Start;

Step 801: Initialize PI and PO syndrome flags

Step 802: Decode all PI codewords;

Step 804: Decode all PO codewords;

Step 806: If all PI and PO codewords are decodable, go to step 812; otherwise, go to step 808

Step 808: Calculate the number of decoding repetitions that occurred for decoding the PI/PO codewords. If the number of decoding repetitions for the PI/PO codewords is larger than a predetermined number, go to step 810; otherwise, go to step 802.

Step 810: Failed.

Step 812: Finished.

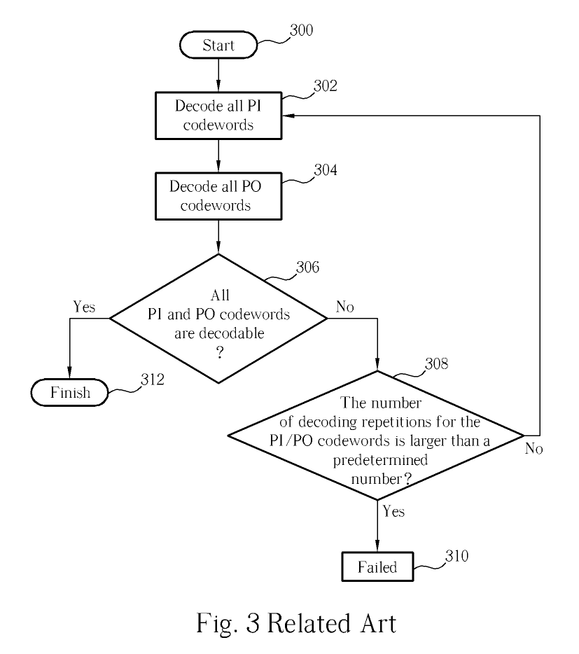

In contrast to the flow shown in FIG. 3, the flow shown in FIG. 8 further comprises a step 801. That is, when the decoding operation is firstly started, all flags corresponding to the PI and PO codewords are de-asserted. In addition, please note that, the steps 802˜812 are all the same as the above-mentioned steps 302˜312, and thus omitted here.

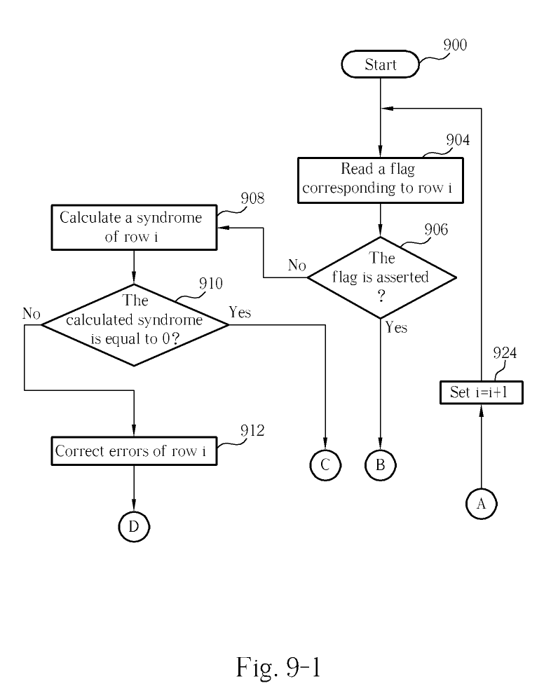

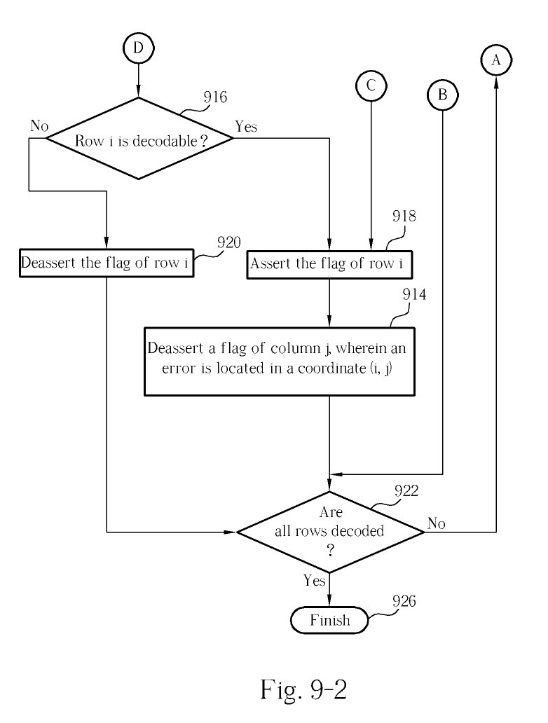

Please refer to FIG. 9-1 and FIG. 9-2, which illustrates the PI decoding operation according to the flow shown in FIG. 8. It comprises the following steps:

Step 900: Start;

Step 904: Read a flag corresponding to row i;

Step 906: Detect whether the flag is asserted; if the flag is asserted, then go to step 922; otherwise, go to step 908;

Step 908: Calculate a syndrome of row i;

Step 910: Detect whether the calculated syndrome is equal to 0; if the calculated syndrome is equal to 0, then go to step 918, otherwise; go to step 912;

Step 912: Correct errors of row i;

Step 916: Detect whether row i is decodable; if row i is decodable, then go to step 918; otherwise, go to step 920;

Step 918: Assert the flag of row i; and then go to step 914;

Step 914: Deassert a flag of column j, wherein an error is located in a coordinate (i, j); and then go to step 922;

Step 920: Deassert the flag of row i;

Step 922: Are all rows decoded? If all rows are decoded, then go to step 926; otherwise, go to step 924;

Step 924: Set i=i+1, and go back to step 904;

Step 926: Finish.

In this embodiment, please note that the original step 602 is removed because all the flags are deasserted first. That is, each flag is cleared before the first PI decoding operation. Therefore, each flag can be directly read without detecting whether the current decoding operation is a repeating decoding operation.

Furthermore, the steps 904˜926 are totally the same as the steps 604˜626 shown in FIG. 6-1 and FIG. 6-2, and further illustration is thus omitted here.

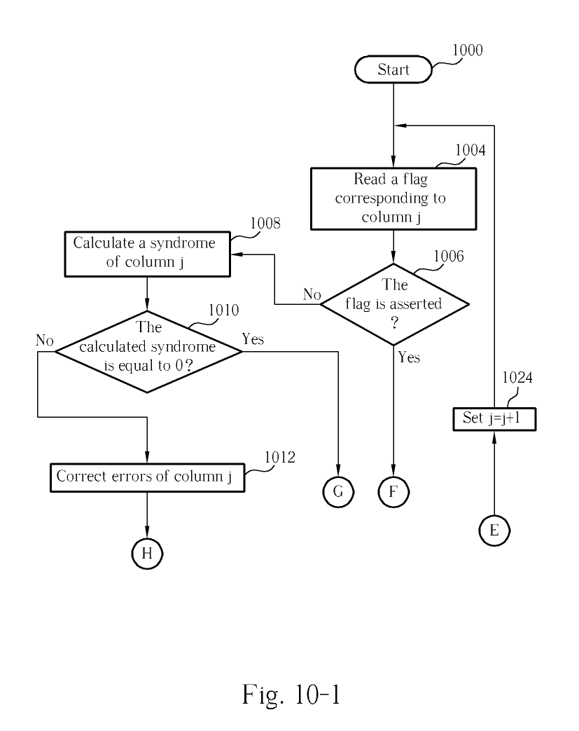

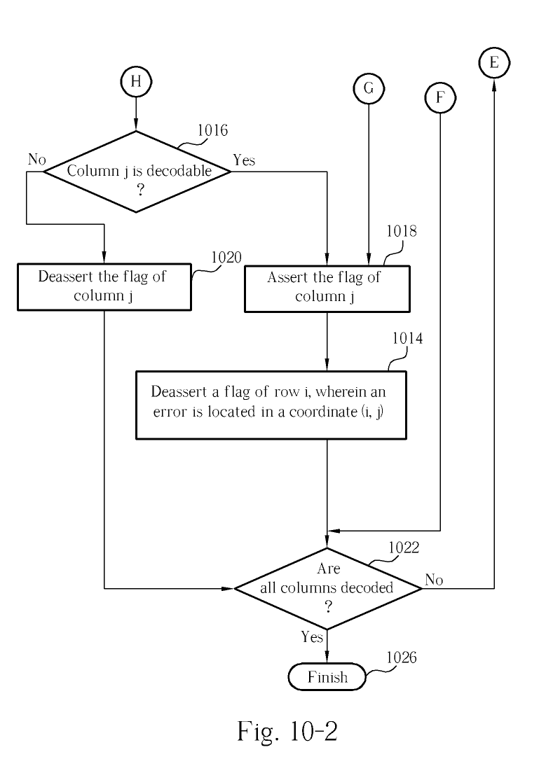

Please refer to FIG. 10-1 and FIG. 10-2, which illustrates the PO decoding operation according to the flow shown in FIG. 8. It comprises the following steps:

Step 1000: Start;

Step 1004: Read a flag corresponding to column j;

Step 1006: Detect whether the flag is asserted; if the flag is asserted, then go to step 1022; otherwise, go to step 1008;

Step 1008: Calculate a syndrome of column j;

Step 1010: Detect if the calculated syndrome is equal to 0; if the calculated syndrome is equal to 0, then go to step 1018, otherwise; go to step 1012;

Step 1012: Correct errors of column j;

Step 1016: Detect whether column j is decodable; if column j is decodable, then go to step 1018; otherwise, go to step 1020;

Step 1018: Assert the flag of column j; and then go to step 1014;

Step 1014: Deassert a flag of row i, wherein an error is located in a coordinate (i, j); and then go to step 1022;

Step 1020: Deassert the flag of column j;

Step 1022: Are all columns decoded? If all columns are decoded, then go to step 1026; otherwise, go to step 1024;

Step 1024: Set j=j+1, and go back to step 1002;

Step 1026: Finish.

In this embodiment, please note that the original step 702 is removed because all the flags are deasserted first. That is, each flag is cleared before the first PO decoding operation. Therefore, each flag can be directly read without detecting whether the current decoding operation is a repeating decoding operation.

Furthermore, the steps 1004˜1026 are totally the same as the steps 704˜726 shown in FIG. 7-1 and FIG. 7-2, and further illustration is thus omitted here.

Please note that the present invention does not limit the number of flags. That is, one flag can correspond to a codeword set having a plurality of codewords. In other words, the present invention decoding device still detects the flag first, and then calculates syndromes of the codeword sets whose flag is not asserted. This change also obeys the spirit of the present invention.

Please note that, the ECC block read from a DVD disk is only utilized as an embodiment, not a limitation of the present invention. In other words, the present invention can be utilized for decoding any other ECC block.

Furthermore, the above-mentioned PI/PO codeword decoding operation is also utilized as a preferred embodiment, not a limitation of the present invention. The present invention can be utilized in other ECC block decoding mechanisms. For example, it is known that the PI/PO decoding operation is based on the polynomials such that the syndrome of each codeword could be determined and the errors of each codeword could be corrected. But in some embodiments, there may be other developed polynomials for calculating syndromes. And the definition of “codeword” may be changed and not limited as a horizontal or a vertical data line (for example, a slope data line). This change also obeys the spirit of the present invention.

In contrast to the related art, the present invention can avoid the repetitive calculating of the syndrome having the value 0. This can save processing time and system resources. In other words, the present invention provides a better and more efficient decoding operation and expends fewer system resources than the related art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for decoding an error correction code (ECC) block comprising:
providing a plurality of flags, wherein each flag is utilized to label at least one data line of the ECC block as an error-free data line; and
detecting whether a flag corresponding to a specific data line is asserted, and skipping calculating a syndrome of the specific data line if the flag is asserted.

2. The method of claim 1, wherein each data line corresponds to a codeword.

3. The method of claim 1, wherein the step of detecting whether the flag is asserted further comprises:
if the flag is not asserted, calculating the syndrome of the specific data line, correcting data of at least one position of the specific data line if the syndrome of the specific data line is not equal to a predetermined value, and asserting the flag if the calculated syndrome is equal to the predetermined value or the data line is decodable.

4. The method of claim 3, wherein the step of correcting data of at least one position of the specific data line further comprises:
deasserting a flag of a second data line corresponding to the position.

5. The method of claim 4, wherein the specific data line is a PI codeword, and the second data line is a PO codeword corresponding to the position.

6. The method of claim 4, wherein the specific data line is a PO codeword, and the second data line is a PI codeword corresponding to the position.

7. The method of claim 1, wherein each flag is utilized to label a data line set having a plurality of data lines of the ECC block as an error-free data line set, and the step of detecting whether the flag is asserted further comprises:
if the flag is not asserted, calculating the syndrome of the specific data line in a specific data line set, correcting data of at least one position of the specific data line if the syndrome of the specific data line is not equal to a predetermined value, and asserting the flag if syndromes of the specific data line set are all equal to the predetermined value or if all the data lines of the specific data line are decodable.

8. The method of claim 7, wherein the step of correcting data of at least one position of the specific data line further comprises:
deasserting a flag of a second data line corresponding to the position.

9. The method of claim 8, wherein the specific data line is a PI codeword, and the second data line is a PO codeword corresponding to the position.

10. The method of claim 8, wherein the specific data line is a PO codeword, and the corresponding data line is a PI codeword corresponding to the position.

11. The method of claim 1, wherein the error correction code (ECC) block is used for optical storage system.

12. A decoding device for decoding an ECC block, the decoding device comprising:
a storage device for storing the ECC block and a plurality of flags, wherein each flag is utilized to label at least one data line of the ECC block as an error-free codeword;
a syndrome calculator; and
a controller for detecting whether a flag corresponding to a data line is asserted, and controlling the syndrome calculator to skip calculating a syndrome of the specific data line if the flag is asserted.

13. The decoding device of claim 12, wherein each data line corresponds to a codeword.

14. The decoding device of claim 12, further comprising:
an error corrector; and
a syndrome-flag circuit;
wherein the controller further controls the syndrome calculator to calculate the syndrome of the specific data line if the flag is not asserted, controls the error corrector to correct data of at least one position of the specific data line if the syndrome of the specific data line is not equal to a predetermined value, and controls the syndrome-flag circuit to assert the flag if the calculated syndrome is equal to the predetermined value or if the data line is decodable.

15. The decoding device of claim 14, wherein the controller further controls the syndrome-flag circuit to deassert a flag of a second data line corresponding to the position.

16. The decoding device of claim 15, wherein the specific data line is a PI codeword, and the second data line is a PO codeword corresponding to the position.

17. The decoding device of claim 15, wherein the specific data line is a PO codeword, and the second data line is a PI codeword corresponding to the position.

18. The decoding device of claim 10 further comprising:
an error corrector; and
a syndrome-flag circuit;
wherein each flag is utilized to label a data line set having a plurality of data lines of the ECC block as an error-free data line set, and the controller further controls the syndrome calculator to calculate the syndrome of the specific data line in a specific data line set if the flag is not asserted, controls the error corrector to correct data of at least one position of the specific data line if the syndrome of the specific data line is not equal to a predetermined value, and controls the syndrome-flag circuit to assert the flag if syndromes of the specific data line set are all equal to the predetermined value or if all data lines of the specific data line set are all decodable.

19. The decoding device of claim 18, wherein the controller further controls the syndrome-flag circuit to deassert a flag of a second data line corresponding to the position.

20. The decoding device of claim 19, wherein the specific data line is a PO codeword, and the second data line is a PI codeword corresponding to the position.

21. The decoding device of claim 19, wherein the specific data line is a PI codeword, and the second data line is a PO codeword corresponding to the position.

22. The decoding device of claim 12, wherein the error correction code (ECC) block is used for optical storage system.
